(19) United States
(12) Patent Application Publication
(10) Pub. No.: US 2017/0344422 A1
(43) Pub. Date: Nov. 30, 2017

(54) SEMICONDUCTOR DEVICES AND SEMICONDUCTOR SYSTEMS

(71) Applicant: SK hynix Inc., Icheon-si Gyeonggi-do (KR)

(72) Inventors: Jung Hyun KWON, Seoul (KR); JINGZHE XU, Seoul (KR); Do Sun HONG, Icheon-si Gyeonggi-do (KR)

(21) Appl. No.: 15/377,024

(22) Filed: Dec. 13, 2016

(30) Foreign Application Priority Data
May 25, 2016 (KR) 10-2016-0063857

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0673

(57) ABSTRACT

A semiconductor device may be provided. The semiconductor device may include an error correction circuit and a verification operation control circuit. The error correction circuit may be configured to output first correction data obtained by correcting an error of first read data inputted through a transmission data signal received, externally from the error correction circuit, as a correction data signal and configured to generate a write control signal according to the number of errors of the first read data. The verification operation control circuit may be configured to receive first correction data through the correction data signal to output the first correction data through an internal correction data signal and configured to generate an internal command signal for storing the first correction data externally from the semiconductor device, based on the write control signal.

### CROSS-REFERENCE TO RELATED APPLICATIONS

The present application claims priority under 35 U.S.C 119(a) to Korean Patent Application No. 10-2016-0063857, filed on May 25, 2016, which is incorporated herein by reference in its entirety.

### BACKGROUND

### 1. Technical Field

Embodiments of the present disclosure may generally relate to semiconductor devices, and more particularly, to semiconductor systems and semiconductor devices relating to errors.

### 2. Related Art

Recently, a DDR2 scheme or a DDR3 scheme receiving and outputting four bit data or eight bit data during each clock cycle time has been used to improve an operation speed of semiconductor devices. If a data transmission speeds of the semiconductor devices increase, the probability of errors occurring may increase while the semiconductor devices are operating. Accordingly, novel design schemes have been proposed to improve the reliability of the data transmissions.

Whenever data is transmitted in semiconductor devices, error codes which are capable of detecting an occurrence of the errors may be generated and transmitted with the data to improve the reliability of the data transmission. The error codes may include an error detection code (EDC) which is capable of detecting errors and an error correction code (ECC) which is capable of correcting the errors by itself.

### SUMMARY

According to an embodiment, a semiconductor system may be provided. According to an embodiment, a semiconductor device may be provided. The semiconductor device may include an error correction circuit and a verification operation control circuit. The error correction circuit may be configured to output first correction data obtained by correcting an error of first read data inputted through a transmission data signal received, externally from the error correction circuit, as a correction data signal and configured to generate a write control signal according to the number of errors of the first read data. The verification operation control circuit may be configured to receive first correction data through the correction data signal to output the first correction data through an internal correction data signal and configured to generate an internal command signal for storing the first correction data externally from the semiconductor device, based on the write control signal.

According to another embodiment, a semiconductor system may include a first semiconductor device and a second semiconductor device. The first semiconductor device may be configured to output first correction data obtained by correcting an error of first read data inputted through a transmission data signal as a correction data signal, generates a write control signal according to the number of errors of the first read data, configured to output the first correction data included in the correction data signal through the transmission data signal based on the write control signal, and configured to output a command signal including a write command or a read command. The second semiconductor device may configured to output the first read data through the transmission data signal outputted from a memory array or configured to store the first correction data into a memory cell of the memory array, based on the command signal.

According to another embodiment, a semiconductor device may include an error correction circuit and a verification operation control circuit. The error correction circuit may configured to output first correction data obtained by correcting an error of first read data inputted through a transmission data signal received, from a memory core circuit, as a correction data signal and configured to generate a write control signal according to the number of errors of the first read data. The verification operation control circuit may configured to receive first correction data through the correction data signal to output the first correction data through an internal correction data signal and configured to generate an internal command signal for storing the first correction data into the memory core circuit, based on the write control signal.

### BRIEF DESCRIPTION OF THE DRAWINGS

FIG. 1 is a block diagram illustrating a representation of an example of a configuration of a semiconductor system according to an embodiment of the present disclosure.

FIG. 2 is a block diagram illustrating a representation of an example of an error correction circuit included in the semiconductor system of FIG. 1.

FIG. 3 is a block diagram illustrating a representation of an example of a verification operation control circuit included in the semiconductor system of FIG. 1.

FIG. 4 is a block diagram illustrating a representation of an example of a configuration of a semiconductor device according to an embodiment of the present disclosure.

FIG. 5 is a block diagram illustrating a representation of an example of a configuration of an electronic system employing the semiconductor device or the semiconductor system illustrated in FIG. 1 to FIG. 4.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

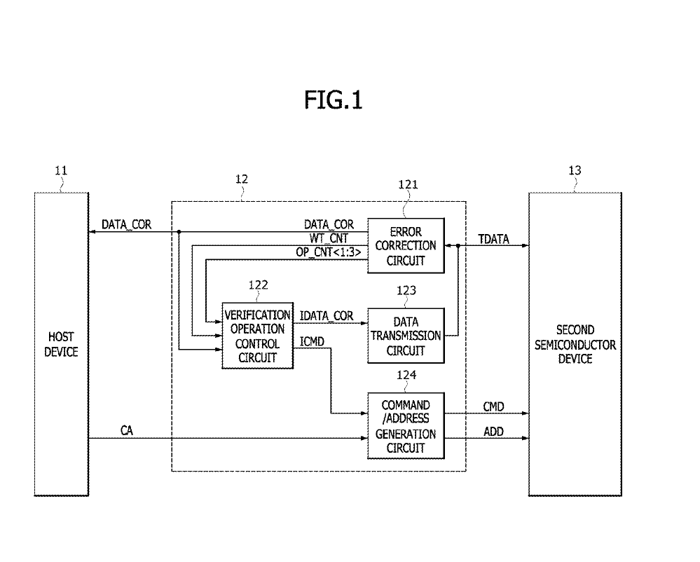

Referring to FIG. 1, a semiconductor system according to an embodiment of the present disclosure may include a host device 11, a first semiconductor device 12, and a second semiconductor device 13.

The host device 11 may output a command/address signal CA and may receive a correction data signal DATA_COR. The host device 11 may output a command and an address through the command/address signal CA. The command/address signal CA may include multiple bits. In order to perform a read operation of the second semiconductor device 13, the host device 11 may output a read command and an address through the command/address signal CA and may receive the correction data signal DATA_COR from the second semiconductor device 13. The correction data signal DATA_COR may include data that is obtained by correcting an error of a transmission data signal TDATA outputted from at least one memory cell of a memory array (not illustrated), which is included in the second semiconductor device 13, corresponding to an address outputted from the host device 11 through the command/address signal CA. In order to perform a write operation of the second semiconductor device 13, the host device 11 may output a write command and an address through the command/address signal CA and may output write data (not illustrated).

The first semiconductor device 12 may include an error correction circuit 121, a verification operation control circuit 122, a data transmission circuit 123, and a command/address generation circuit 124. The first semiconductor device 12 may be a controller which controls an input and output (I/O) operation of the second semiconductor device 13.

If a read operation of the second semiconductor device 13 is performed, the error correction circuit 121 may receive the transmission data signal TDATA and may perform an error correction operation to generate the correction data signal DATA_COR, a write control signal WT_CNT, and first to third operation control signals OP_CNT<1:3>. During the read operation, the transmission data signal TDATA may include read data and an error correction code which are outputted from a memory array (not illustrated) included in the second semiconductor device 13. Each of the read data and the error correction code may include multiple bits. The error correction code may include information on a logic level of the read data and may be used for error correction of the read data. During the read operation, the error correction circuit 121 may receive first read data through the transmission data signal TDATA which is outputted from a memory array (not illustrated) of the second semiconductor device 13 in response to an address signal ADD. The error correction circuit 121 may output first correction data, which is obtained by correcting an error of the first read data, through the correction data signal DATA_COR. The error correction circuit 121 may generate the write control signal WT_CNT according to the number of errors of the first read data. If the number of errors of the first read data is equal to or greater than a predetermined number, the error correction circuit 121 may generate the write control signal WT_CNT to execute a hard error discrimination operation. The hard error discrimination operation may include a first verification operation and a second verification operation and may be an operation of discriminating a soft error or a hard error with respect to the error location of the first read data. The soft error may correspond to an error which temporarily occurs due to noise on a line transmitting data or temperature variation of the memory array storing the data. The hard error may correspond to an error whereby wrong data is continuously outputted from the memory array due to a defect of a line transmitting the data or a defect of a memory array storing the data. If the first verification operation is performed after the hard error discrimination operation starts, the error correction circuit 121 may store the error location of the first read data. The predetermined number may be set to be less than the number of errors which can be corrected by the error correction circuit 121 at a time. For example, if the first read data includes “N”-number of bits and a maximum number “M” of erroneous bits corrected by the error correction circuit 121 at a time is less than the number “N”, the predetermined number may be set to be a number “K” which is less than the number “M”. The numbers “N”, “M”, and “K” may be natural numbers.

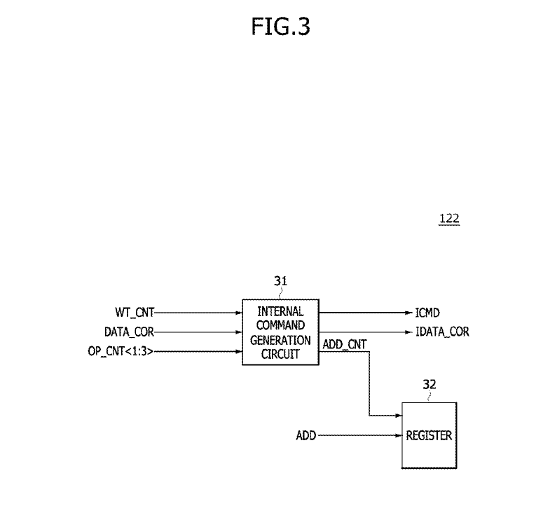

The error correction circuit 121 may receive second read data outputted from the memory array storing the first read data, through the transmission data signal TDATA during the first verification operation. The second read data may be the first correction data which are obtained by correcting an error of the first read data after the first verification operation starts. The first correction data may be stored in the memory array, and the first correction data stored in the memory array may be outputted from the memory array as the second read data. The error correction circuit 121 may output second correction data which is obtained by correcting an error of the second read data, through the correction data signal DATA_COR during the first verification operation. The error correction circuit 121 may compare an error location of the first read data stored therein with an error location of the second read data stored therein to generate the first to third operation control signals OP_CNT<1:3>. If the error location of the first read data is totally inconsistent with the error location of the second read data, the error correction circuit 121 may generate the first operation control signal OP_CNT<1> which is enabled. If the error location of the first read data is totally consistent with the error location of the second read data, the error correction circuit 121 may generate the second operation control signal OP_CNT<2> which is enabled. If the error location of the first read data is partially consistent with the error location of the second read data, the error correction circuit 121 may generate the third operation control signal OP_CNT<3> which is enabled. If the first operation control signal OP_CNT<1> is enabled, the error of the first read data may be regarded as a soft error and a hard error verification operation may terminate. If the second operation control signal OP_CNT<2> is enabled, the error of the first read data may be regarded as a hard error and the address signal ADD corresponding to a location of the first read data may be stored in a register (32 of FIG. 3). Memory cells corresponding to the address signal ADD stored in the register (32 of FIG. 3) may be replaced with a redundancy memory cell by a repair operation. If the third operation control signal OP_CNT<3> is enabled, the second verification operation may start. If the second verification operation starts, the error correction circuit 121 may store the error location of the second read data. In an embodiment, for example, totally consistent may indicate all of the error locations of the first read data stored within the memory array match all of the error locations of all of the second read data stored within the memory array. In an embodiment, for example, totally inconsistent may indicate none of the error locations of the first read data stored within the memory array match any of the error locations of all of the second read data stored within the memory array. In an embodiment, for example, partially consistent may indicate less than all, but more than none, of the error locations of the first read data stored within the memory array match the error locations of the second read data stored within the memory array.

The error correction circuit 121 may receive third read data which are outputted from a memory array (not illustrated) storing the second read data, through the transmission data signal TDATA during the second verification operation. The third read data may be the second correction data which are obtained by correcting an error of the second read data and stored in the memory array, and the third read data may be outputted from the memory array after the second verification operation starts. The error correction circuit 121 may output third correction data which is obtained by correcting an error of the third read data, through the correction data signal DATA_COR during the second verification operation. The error correction circuit 121 may compare an error location of the second read data stored therein with an error location of the third read data stored therein to generate the first to third operation control signals OP_CNT<1:3>. If the error location of the second read data is totally inconsistent with the error location of the third read data, the error correction circuit 121 may generate the first operation control signal OP_CNT<1> which is enabled. If the error location of the second read data is totally consistent with the error location of the third read data, the error correction circuit 121 may generate the second operation control signal OP_CNT<2> which is enabled. If the error location of the second read data is partially consistent with the error location of the third read data, the error correction circuit 121 may generate the third operation control signal OP_CNT<3> which is enabled. If the first operation control signal OP_CNT<1> is enabled, the error of the first read data may be regarded as a soft error and a hard error verification operation may terminate. If the second operation control signal OP_CNT<2> and the third operation control signal OP_CNT<3> are enabled, the error of the first read data may be regarded as a hard error and the address signal ADD corresponding to a location of the first read data may be stored in the register (32 of FIG. 3). The memory cells corresponding to the address signal ADD stored in the register (32 of FIG. 3) may be replaced with a redundancy memory cell by a repair operation. In an embodiment, for example, totally consistent may indicate all of the error locations of the second read data stored within the memory array match all of the error locations of all of the third read data stored within the memory array. In an embodiment, for example, totally inconsistent may indicate none of the error locations of the second read data stored within the memory array match any of the error locations of all of the third read data stored within the memory array. In an embodiment, for example, partially consistent may indicate less than all, but more than none, of the error locations of the second read data stored within the memory array match the error locations of the third read data stored within the memory array.

The verification operation control circuit 122 may receive the correction data signal DATA_COR to generate an internal correction data signal IDATA_COR and an internal command signal ICMD, in response to the write control signal WT_CNT and the first to third operation control signals OP_CNT<1:3>. If the write control signal WT_CNT is enabled to execute the first verification operation, the verification operation control circuit 122 may output the first correction data included in the correction data signal DATA_COR through the internal correction data signal IDATA_COR. If the first verification operation starts, the verification operation control circuit 122 may generate the internal command signal ICMD for writing the first correction data included in the internal correction data signal IDATA_COR into the second semiconductor device 13. The internal command signal ICMD may include a write command for writing the first correction data into the second semiconductor device 13. The verification operation control circuit 122 may generate the internal command signal ICMD for reading the first correction data stored in the second semiconductor device 13 after the first correction data included in the internal correction data signal IDATA_COR are stored in the second semiconductor device 13. The internal command signal ICMD may include a read command for reading out the first correction data which are stored in the second semiconductor device 13. The verification operation control circuit 122 may perform the second verification operation or may terminate the hard error discrimination operation, in response to the first to third operation control signals OP_CNT<1:3>. If the first operation control signal OP_CNT<1> is enabled during the first verification operation, the verification operation control circuit 122 may regard an error of the first read data stored in the memory array (not illustrated) as a soft error to terminate the hard error discrimination operation. If the second operation control signal OP_CNT<2> is enabled during the first verification operation, the verification operation control circuit 122 may regard an error of the first read data stored in the memory array (not illustrated) as a hard error to store the address signal ADD of the first read data in the register (32 of FIG. 3). If the third operation control signal OP_CNT<3> is enabled during the first verification operation, a second verification mode may start and the verification operation control circuit 122 may output the second correction data included in the correction data signal DATA_COR through the internal correction data signal IDATA_COR. If the first operation control signal OP_CNT<1> is enabled during the second verification operation, the verification operation control circuit 122 may regard an error of the first read data stored in the memory array (not illustrated) as a soft error to terminate the hard error discrimination operation. If the second and third operation control signals OP_CNT<2:3> are enabled during the second verification operation, the verification operation control circuit 122 may regard an error of the first read data stored in the memory array (not illustrated) as a hard error to store the address signal ADD of the first read data in the register (32 of FIG. 3).

The data transmission circuit 123 may receive the internal correction data signal IDATA_COR and may output the internal correction data signal IDATA_COR as the transmission data signal TDATA. The data transmission circuit 123 may output correction data included in the internal correction data signal IDATA_COR through the transmission data signal TDATA. The data transmission circuit 123 may include an error correction code generation circuit (not illustrated) which generates an error correction code from the correction data signal DATA_COR. The data transmission circuit 123 may generate an error correction code for correcting an error of correction data included in the internal correction data signal IDATA_COR and may output the correction data and the error correction code to the second semiconductor device 13 through the transmission data signal TDATA. The data transmission circuit 123 may generate an error correction code from the first correction data inputted through the internal correction data signal IDATA_COR and may output the first correction data and the error correction code through the transmission data signal TDATA, during the first verification operation. The data transmission circuit 123 may generate an error correction code from the second correction data inputted through the internal correction data signal IDATA_COR and may output the second correction data and the error correction code through the transmission data signal TDATA, during the second verification operation.

The command/address generation circuit 124 may receive the command/address signal CA and the internal command signal ICMD to generate a command signal CMD and the address signal ADD. The command/address generation circuit 124 may output a write command or a read command included in the command/address signal CA through the command signal CMD and may output an address included in the command/address signal CA through the address signal ADD. The command/address generation circuit 124 may output a write command or a read command included in the internal command signal ICMD through the command signal CMD. The command/address generation circuit 124 may latch an address which is received through the command/address signal CA during the read operation and may output the latched address through the address signal ADD during the first verification operation and the second verification operation.

The second semiconductor device 13 may receive data through the transmission data signal TDATA to store the data in a memory array (not illustrated) or may output the data stored in the memory array (not illustrated) through the transmission data signal TDATA, in response to the command signal CMD and the address signal ADD. If the write command is inputted to the second semiconductor device 13 through the command signal CMD, the second semiconductor device 13 may store the data inputted through the transmission data signal TDATA in at least one memory cell (not illustrated) of the second semiconductor device 13 corresponding to an address inputted through the address signal ADD. If the read command is inputted to the second semiconductor device 13 through the command signal CMD, the second semiconductor device 13 may output the data stored in at least one memory cell of the second semiconductor device 13 corresponding to an address of the address signal ADD through the transmission data signal TDATA. The second semiconductor device 13 may be a memory device including a plurality of memory cells. The second semiconductor device 13 may be a nonvolatile memory device such as a flash memory or a phase change random access memory (PcRAM) or may be a volatile memory device such as a dynamic random access memory (DRAM) or a static random access memory (SRAM), etc.

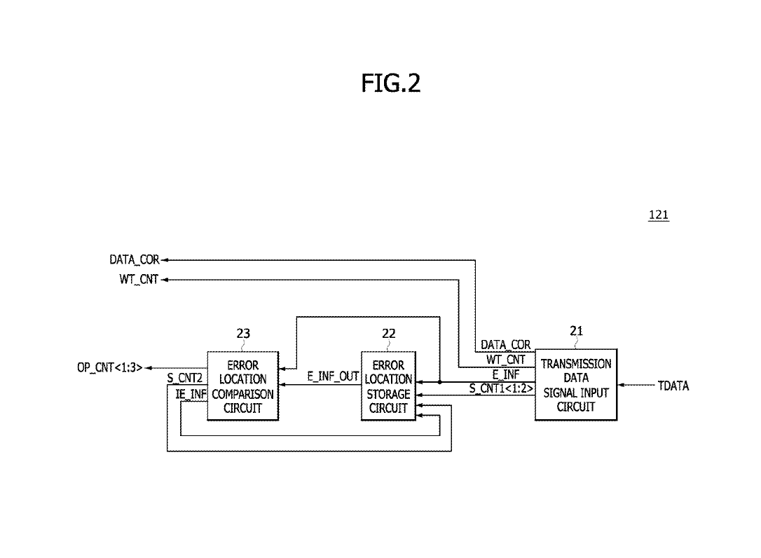

Referring to FIG. 2, the error correction circuit 121 may include a transmission data signal input circuit 21, an error location storage circuit 22, and an error location comparison circuit 23.

The transmission data signal input circuit 21 may receive the transmission data signal TDATA and may perform an error correction operation to generate the correction data signal DATA_COR, the write control signal WT_CNT, an error location information signal E_INF, and a first storage control signal S_CNT1<1:2>. The error location information signal E_INF may include information on an error location of read data included in the transmission data signal TDATA. The error location information signal E_INF may be stored in the error location storage circuit 22 or information on error location of the error location information signal E_INF stored in the error location storage circuit 22 may be outputted as an error location information output signal E_INF_OUT, according to a logic level combination of the first storage control signal S_CNT1<1:2>. For example, the transmission data signal input circuit 21 may generate the first storage control signal S_CNT1<1:2> having a first logic level combination to store the error location information signal E_INF in the error location storage circuit 22 and may generate the first storage control signal S_CNT1<1:2> having a second logic level combination to output the error location information stored in the error location storage circuit 22 as the error location information output signal E_INF_OUT. The transmission data signal input circuit 21 may receive the first read data through the transmission data signal TDATA during the read operation. The transmission data signal input circuit 21 may correct an error of the first read data inputted through the transmission data signal TDATA to generate the first correction data during the read operation. The first correction data may be outputted through the correction data signal DATA_COR. The transmission data signal input circuit 21 may generate the write control signal WT_CNT according to the number of errors of the first read data. If the number of errors of the first read data is equal to or greater than a predetermined number, the transmission data signal input circuit 21 may generate the write control signal WT_CNT after the hard error discrimination operation starts. The hard error discrimination operation may be an operation of discriminating a soft error or a hard error with respect to the error location of the first read data. If the first verification operation is performed after the hard error discrimination operation starts, the transmission data signal input circuit 21 may output the error location information signal E_INF including the information on the error location of the first read data. If the first verification operation starts, the transmission data signal input circuit 21 may generate the first storage control signal S_CNT1<1:2> having a first logic level combination. If the second read data is inputted to the transmission data signal input circuit 21 through the transmission data signal TDATA during the first verification operation, the transmission data signal input circuit 21 may correct an error of the second read data to generate the second correction data. The second correction data may be outputted through a correction data signal. The transmission data signal input circuit 21 may output the error location information signal E_INF including information on the error location of the second read data. The transmission data signal input circuit 21 may generate the first storage control signal S_CNT1<1:2> having a second logic level combination. If third read data are inputted to the transmission data signal input circuit 21 through the transmission data signal TDATA during the second verification operation, the transmission data signal input circuit 21 may correct an error of the third read data to generate third correction data. The third correction data may be outputted through the correction data signal DATA_COR. The transmission data signal input circuit 21 may output the error location information signal E_INF including information on the error location of the third read data. The transmission data signal input circuit 21 may generate the first storage control signal S_CNT1<1:2> having a second logic level combination.

The error location storage circuit 22 may store information on an error location included in the error location information signal E_INF or an internal error location information signal IE_INF or may output the information on the error location stored therein through the error location information output signal E_INF_OUT, in response to the first storage control signal S_CNT1<1:2> and a second storage control signal S_CNT2. The error location storage circuit 22 may store the error location information signal E_INF therein or may output the error location information signal E_INF as the error location information output signal E_INF_OUT, in response to the first storage control signal S_CNT1<1:2>. If the first storage control signal S_CNT1<1:2> has the first logic level combination, the error location storage circuit 22 may store the information on an error location included in the error location information signal E_INF. If the first storage control signal S_CNT1<1:2> has the second logic level combination, the error location storage circuit 22 may output the information on the stored error location through the error location information output signal E_INF_OUT. If the second storage control signal S_CNT2 is enabled, the error location storage circuit 22 may store information on an error location included in the internal error location information signal IE_INF. The error location storage circuit 22 may be realized using a latch circuit.

The error location comparison circuit 23 may compare the error location information signal E_INF with the error location information output signal E_INF_OUT to generate the first to third operation control signals OP_CNT<1:3>, the second storage control signal S_CNT2, and the internal error location information signal IE_INF. If the information on the error location included in the error location information signal E_INF is totally inconsistent with the information on the error location included in the error location information output signal E_INF_OUT, the error location comparison circuit 23 may generate the first operation control signal OP_CNT<1> which is enabled. If the information on the error location included in the error location information signal E_INF is totally consistent with the information on the error location included in the error location information output signal E_INF_OUT, the error location comparison circuit 23 may generate the second operation control signal OP_CNT<2> which is enabled. If the information on the error location included in the error location information signal E_INF is partially consistent with the information on the error location included in the error location information output signal E_INF_OUT, the error location comparison circuit 23 may generate the third operation control signal OP_CNT<3> and the second storage control signal S_CNT2 which are enabled and may output the information on the error location included in the error location information signal E_INF through the internal error location information signal IE_INF. In an embodiment, for example, totally consistent may indicate all of the information on the error location included in the error location information signal E_INF matches all of the information on the error location included in the error location information output signal E_INF_OUT. In an embodiment, for example, totally inconsistent may indicate none of the information on the error location included in the error location information signal E_INF matches any of the information on the error location included in the error location information output signal E_INF_OUT. In an embodiment, for example, partially consistent may indicate less than all, but more than none, of the error location included in the error location information signal E_INF matches the information on the error location included in the error location information output signal E_INF_OUT.

As described above, the transmission data signal input circuit 21 may correct the error of the first read data included in the transmission data signal TDATA to generate the first correction data during the read operation. The first correction data may be outputted through the correction data signal DATA_COR. If the number of the errors of the first read data is equal to or greater than the predetermined number, the transmission data signal input circuit 21 may generate the write control signal WT_CNT after the first verification operation starts, may generate the error location information signal E_INF including the information on the error location of the first read data, and may generate the first storage control signal S_CNT1<1:2> having the first logic level combination. The error location storage circuit 22 may store the information on the error location of the first read data included in the error location information signal E_INF in response to the first storage control signal S_CNT1<1:2> having the first logic level combination. If the second read data is inputted to the transmission data signal input circuit 21 through the transmission data signal TDATA after the first correction data is written into the second semiconductor device 13, the transmission data signal input circuit 21 may correct the error of the second read data to generate the second correction data. The second correction data may be outputted through the correction data signal DATA_COR. The transmission data signal input circuit 21 may generate the error location information signal E_INF including the information on the error location of the second read data and may generate the first storage control signal S_CNT1<1:2> having the second logic level combination. The error location storage circuit 22 may output the information on the error location of the first read data stored therein through the error location information output signal E_INF_OUT in response to the first storage control signal S_CNT1<1:2> having the second logic level combination. The error location comparison circuit 23 may compare the information on the error location of the second read data included in the error location information signal E_INF with the information on the error location of the first read data included in the error location information output signal E_INF_OUT to generate the first to third operation control signals OP_CNT<1:3>. If the information on the error location of the second read data included in the error location information signal E_INF is partially consistent with the information on the error location of the first read data included in the error location information output signal E_INF_OUT, the error location comparison circuit 23 may generate the third operation control signal OP_CNT<3> and the second storage control signal S_CNT2 which are enabled and may output the information on the error location of the second read data included in the error location information signal E_INF through the internal error location information signal IE_INF. The error location storage circuit 22 may store the information on the error location of the second read data included in the internal error location information signal IE_INF in response to the second storage control signal S_CNT2. During the second verification operation, the transmission data signal input circuit 21 may correct the error of the third read data to generate the third correction data if the third read data is inputted to the transmission data signal input circuit 21 through the transmission data signal TDATA after the second correction data is written into the second semiconductor device 13. The third correction data may be outputted through the correction data signal DATA_COR. The transmission data signal input circuit 21 may generate the error location information signal E_INF including the information on the error location of the third read data and may generate the first storage control signal S_CNT1<1:2> having the second logic level combination. The error location storage circuit 22 may output the information on the error location of the second read data stored therein through the error location information output signal E_INF_OUT in response to the first storage control signal S_CNT1<1:2> having the second logic level combination. The error location comparison circuit 23 may compare the information on the error location of the third read data included in the error location information signal E_INF with the information on the error location of the second read data included in the error location information output signal E_INF_OUT to generate the first to third operation control signals OP_CNT<1:3>.

Referring to FIG. 3, the verification operation control circuit 122 may include an internal command generation circuit 31 and a register 32.

The internal command generation circuit 31 may generate the internal command signal ICMD and the internal correction data signal IDATA_COR in response to the write control signal WT_CNT, the correction data signal DATA_COR, and the first to third operation control signals OP_CNT<1:3>. If the write control signal WT_CNT is enabled, the internal command generation circuit 31 may output correction data included in the correction data signal DATA_COR through the internal correction data signal IDATA_COR and may generate the internal command signal ICMD for reading out the correction data after the correction data are written into a memory array included in the second semiconductor device 13. If the first operation control signal OP_CNT<1> is enabled, the internal command generation circuit 31 may generate an address storage control signal ADD_CNT which is enabled. If the second operation control signal OP_CNT<2> is enabled, the hard error discrimination operation may terminate and the internal command generation circuit 31 may not generate any output signals. If the third operation control signal OP_CNT<3> is enabled during the first verification operation, the internal command generation circuit 31 may output the correction data included in the correction data signal DATA_COR though the internal correction data signal IDATA_COR and may generate the internal command signal ICMD for reading out the correction data after the correction data are written into the memory array included in the second semiconductor device 13. If the third operation control signal OP_CNT<3> is enabled during the second verification operation, the internal command generation circuit 31 may generate the address storage control signal ADD_CNT which is enabled.

The register 32 may store the address signal ADD in response to the address storage control signal ADD_CNT. The register 32 may be realized using a nonvolatile memory or a fuse array which is capable of storing the address signal ADD. The memory cells corresponding to the address signal ADD stored in the register 32 may be replaced with redundancy memory cells by a repair operation.

As described above, the semiconductor system according to a present embodiment may perform an error correction operation during the read operation if the first read data is inputted through the transmission data signal TDATA. If the number of errors of the first read data is equal to or greater than the predetermined number, the semiconductor system may generate the write control signal WT_CNT to enter the first verification operation. During the first verification operation, the error location of the first read data may be stored in the error correction circuit 121, first correction data obtained by correcting the errors of the first read data may be stored in the memory array (i.e., memory cell) storing the first read data, and the first correction data may be outputted from the memory array (i.e., the memory cell) as the second read data. During the first verification operation, the error location of the first read data may be compared with the error location of the second read data to discriminate whether the error of the first read data is a hard error or a soft error. If the error location of the first read data is totally consistent with the error location of the second read data, the memory cells in which the first read data are stored may be regarded as having a defect causing a hard error. If the error location of the first read data is totally inconsistent with the error location of the second read data, the memory cells in which the first read data are stored may be regarded as having a defect causing a soft error. If the error location of the first read data is partially consistent with the error location of the second read data, the second verification operation may start. During the second verification operation, the error location of the second read data may be stored in the error correction circuit 121, second correction data obtained by correcting the error of the second read data may be stored in the memory array (i.e., memory cell) storing the second read data, and the second correction data may be outputted from the memory array (i.e., the memory cell) as third read data. During the second verification operation, the error location of the second read data may be compared with the error location of the third read data to discriminate whether the error of the second read data is a hard error or a soft error. If the error location of the second read data is totally or partially consistent with the error location of the second read data, the memory cells in which the second read data are stored may be regarded as having a hard defect causing a hard error. If the error location of the second read data is totally inconsistent with the error location of the third read data, the memory cells in which the second read data are stored may be regarded as having a defect causing a soft error. As such, if the number of errors of the read data is equal to or greater than the predetermined number during the read operation, operations of writing and reading the correction data may be repeatedly performed to test whether an error occurs at the same location. Accordingly, it may be possible to discriminate whether a hard error occurs in the memory array.

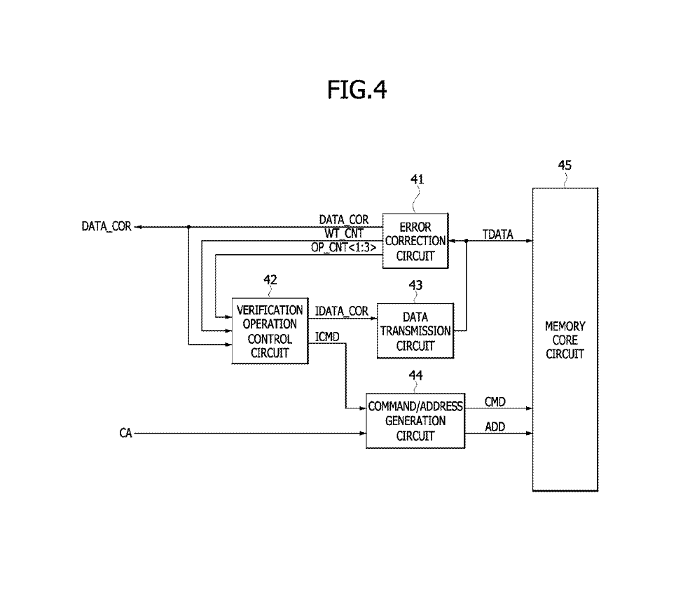

Referring to FIG. 4, a semiconductor device according to an embodiment may include an error correction circuit 41, a verification operation control circuit 42, a data transmission circuit 43, a command/address generation circuit 44, and a memory core circuit 45.

If a read operation is performed, the error correction circuit 41 may receive transmission data signal TDATA and may perform an error correction operation to generate a correction data signal DATA_COR, a write control signal WT_CNT, and first to third operation control signals OP_CNT<1:3>. The transmission data signal TDATA may include read data and an error correction code which are outputted from a memory array (not illustrated) included in the memory core circuit 45 during the read operation. Each of the read data and the error correction code may include multiple bits. The error correction code may be a code which is used for error correction of the read data and may include information on logic levels of the read data. During the read operation, the error correction circuit 41 may receive first read data through the transmission data signal TDATA which are outputted from a memory array (not illustrated) included in the memory core circuit 45 in response to an address signal ADD. The error correction circuit 41 may output first correction data obtained by correcting an error of the first read data through the correction data signal DATA_COR. The error correction circuit 41 may generate the write control signal WT_CNT according to the number of errors of the first read data. If the number of errors of the first read data is equal to or greater than a predetermined number, the error correction circuit 41 may generate the write control signal WT_CNT to enter a hard error discrimination operation. The hard error discrimination operation may include a first verification operation and a second verification operation and may be an operation of discriminating a soft error or a hard error with respect to the error location of the first read data. If a first verification operation is performed after the hard error discrimination operation starts, the error correction circuit 41 may store the error location of the first read data. The error correction circuit 41 may receive second read data outputted from the memory array storing the first read data through the transmission data signal TDATA during the first verification operation. The second read data may be the first correction data which are obtained by correcting an error of the first read data after the first verification operation starts. The first correction data may be stored in the memory array, and the first correction data stored in the memory array may be outputted from the memory array as the second read data. The error correction circuit 41 may output second correction data obtained by correcting an error of the second read data through the correction data signal DATA_COR during the first verification operation. The error correction circuit 41 may compare an error location of the first read data stored therein with an error location of the second read data stored therein to generate the first to third operation control signals OP_CNT<1:3>. The error correction circuit 41 may receive third read data outputted from the memory array (not illustrated) storing the second read data through the transmission data signal TDATA during the second verification operation. The third read data may be the second correction data which are obtained by correcting an error of the second read data after the second verification operation starts. The second correction data may be stored in the memory array, and the second correction data stored in the memory array may be outputted from the memory array as the third read data. The error correction circuit 41 may output third correction data obtained by correcting an error of the third read data through the correction data signal DATA_COR during the second verification operation. The error correction circuit 41 may compare an error location of the second read data stored therein with an error location of the third read data stored therein to generate the first to third operation control signals OP_CNT<1:3>. The error correction circuit 41 may have the same configuration as the error correction circuit 121 described with reference to FIG. 1. Thus, a description of the error correction circuit 41 will be omitted hereinafter.

The verification operation control circuit 42 may receive the correction data signal DATA_COR to generate an internal correction data signal IDATA_COR and an internal command signal ICMD, in response to the write control signal WT_CNT and the first to third operation control signals OP_CNT<1:3>. If the write control signal WT_CNT is enabled to perform the first verification operation, the verification operation control circuit 42 may output the first correction data included in the correction data signal DATA_COR through the internal correction data signal IDATA_COR. The verification operation control circuit 42 may generate the internal command signal ICMD for writing the first correction data into the memory core circuit 45 or reading out the first correction data stored in the memory core circuit 45 during the first verification operation. The verification operation control circuit 42 may perform the second verification operation or may terminate the hard error discrimination operation, in response to the first to third operation control signals OP_CNT<1:3>. The verification operation control circuit 42 may have the same configuration as the verification operation control circuit 122 described with reference to FIG. 1. Thus, a description of the verification operation control circuit 42 will be omitted hereinafter.

The data transmission circuit 43 may receive the internal correction data signal IDATA_COR and may output the internal correction data signal IDATA_COR as the transmission data signal TDATA. The data transmission circuit 43 may output correction data included in the internal correction data signal IDATA_COR through the transmission data signal TDATA. The data transmission circuit 43 may include an error correction code generation circuit (not illustrated) generating an error correction code from the correction data signal DATA_COR. The data transmission circuit 43 may generate an error correction code for correcting an error of correction data included in the internal correction data signal IDATA_COR and may output the correction data and the error correction code to the memory core circuit 45 through the transmission data signal TDATA. The data transmission circuit 43 may generate an error correction code from first correction data inputted through the internal correction data signal IDATA_COR and may output the first correction data and the error correction code through the transmission data signal TDATA, during the first verification operation. The data transmission circuit 43 may generate an error correction code from second correction data inputted through the internal correction data signal IDATA_COR and may output the second correction data and the error correction code through the transmission data signal TDATA, during the second verification operation.

The command/address generation circuit 44 may receive the command/address signal CA and the internal command signal ICMD to generate a command signal CMD and the address signal ADD. The command/address generation circuit 44 may output a write command or a read command included in the command/address signal CA through the command signal CMD and may output an address included in the command/address signal CA through the address signal ADD. The command/address generation circuit 44 may output a write command or a read command included in the internal command signal ICMD through the command signal CMD. The command/address generation circuit 44 may latch an address received through the command/address signal CA during the read operation and may output the latched address through the address signal ADD during the first verification operation and the second verification operation.

As described above, the semiconductor device illustrated in FIG. 4 may include the error correction circuit 41 and the verification operation control circuit 42 in addition to the memory core circuit 45, in contrast to the second semiconductor device 13 illustrated in FIG. 1. Thus, the semiconductor device illustrated in FIG. 4 may internally perform the hard error discrimination operation.

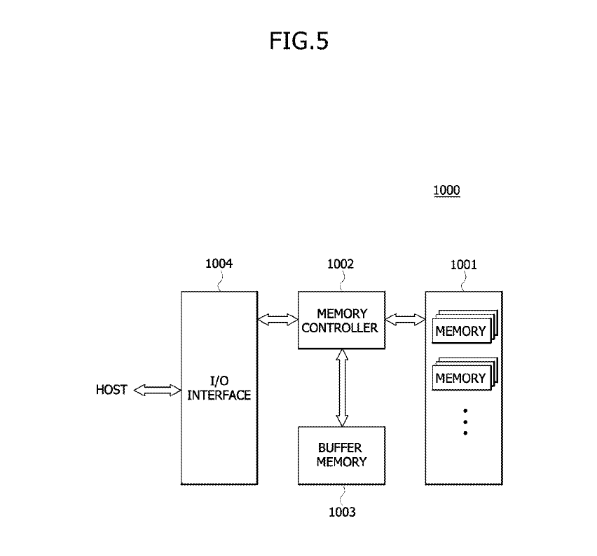

The semiconductor device or the semiconductor system described with reference to FIGS. 1 to 4 may be applied to an electronic system that includes a memory system, a graphic system, a computing system, a mobile system, or the like. For example, as illustrated in FIG. 5, an electronic system 1000 according an embodiment may include a data storage circuit 1001, a memory controller 1002, a buffer memory 1003, and an input/output (I/O) interface 1004.

The data storage circuit 1001 may store data which are outputted from the memory controller 1002 or may read and output the stored data to the memory controller 1002, according to a control signal generated from the memory controller 1002. The data storage circuit 1001 may include the second semiconductor device 13 illustrated in FIG. 1 or the semiconductor device illustrated in FIG. 4. The data storage circuit 1001 may include a nonvolatile memory that can retain their stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. The memory controller 1002 may include the first semiconductor device 12 illustrated in FIG. 1. Although FIG. 5 illustrates the memory controller 1002 with a single block, the memory controller 1002 may include one controller for controlling the data storage circuit 1001 comprised of a nonvolatile memory and another controller for controlling the buffer memory 1003 comprised of a volatile memory.

The buffer memory 1003 may temporarily store the data which are processed by the memory controller 1002. That is, the buffer memory 1003 may temporarily store the data which are outputted from or to be inputted to the data storage circuit 1001. The buffer memory 1003 may store the data which are outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM, or a static random access memory (SRAM), etc.

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data generated from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE), etc.

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

According to the present disclosure, first read data and second read data may be outputted from the same memory cell, and an error location of the first read data may be compared with an error location of the second read data to discriminate whether an error of the memory cell is a hard error or a soft error.

What is claimed is:

1. A semiconductor device comprising:
an error correction circuit configured to output first correction data obtained by correcting an error of first read data inputted through a transmission data signal received, externally from the error correction circuit, as a correction data signal and configured to generate a write control signal according to the number of errors of the first read data; and
a verification operation control circuit configured to receive first correction data through the correction data signal to output the first correction data through an internal correction data signal and configured to generate an internal command signal for storing the first correction data externally from the semiconductor device, based on the write control signal.

2. The device of claim 1, wherein if the number of errors of the first read data is equal to or greater than a predetermined number, a first verification operation starts and the error correction circuit generates the write control signal.

3. The device of claim 2, wherein the predetermined number is set to be less than the number of errors that the error correction circuit corrects at a time.

4. The device of claim 2, wherein the error correction circuit stores an error location of the first read data if the first verification operation starts.

5. The device of claim 1, wherein the verification operation control circuit generates the internal command signal for reading out the first correction data stored externally from the semiconductor device as second read data through the transmission data signal.

6. The device of claim 5, wherein the error correction circuit compares an error location of the second read data inputted through the transmission data signal with an error location of the first read data to generate first to third operation control signals.

7. The device of claim 6,
wherein if the error location of the first read data is totally inconsistent with the error location of the second read data, the first operation control signal is enabled, and
wherein if the error location of the first read data is totally consistent with the error location of the second read data, the second operation control signal is enabled.

8. The device of claim 6, wherein if the second operation control signal is enabled, the verification operation control circuit stores an address relating to a storage location externally from the semiconductor device within the verification operation control circuit.

9. The device of claim 6, wherein if the error location of the first read data is partially consistent with the error location of the second read data, the third operation control signal is enabled.

10. The device of claim 9, wherein if the third operation control signal is enabled, the second verification operation starts, the verification operation control circuit receives second correction data obtained by correcting the second read data through the correction data signal to output the second correction data as the internal correction data signal, and the verification operation control circuit generates the internal command signal to store the second correction data externally from the semiconductor device.

11. The device of claim 10, wherein the verification operation control circuit generates the internal command signal for reading out the second correction data stored externally from the semiconductor device through the transmission data signal as third read data.

12. The device of claim 11, wherein the error correction circuit compares an error location of the third read data inputted through the transmission data signal with an error location of the second read data to generate the first to third operation control signals.

13. The device of claim 12, wherein if the second and third operation control signals are enabled, the verification operation control circuit stores an address relating to a storage location externally from the semiconductor device within the verification operation control circuit.

14. The device of claim 1, wherein the error correction circuit includes:
a transmission data signal input circuit configured to receive the transmission data signal and configured to correct an error of the first read data to generate a correction data signal, a write control signal, an error location information signal, and a first storage control signal;
an error location storage circuit configured to store an error location information signal or an internal error location information signal or configured to output an error location information output signal, based on the first storage control signal and a second storage control signal; and
an error location comparison circuit configured to compare the error location information signal with the error location information output signal to generate first to third operation control signals and the second storage control signal and configured to generate the internal error location information signal from the error location information signal.

15. The device of claim 1, wherein the verification operation control circuit includes:
an internal command generation circuit configured to receive the correction data signal to generate the internal command signal and an internal correction data signal based on the write control signal and first to third operation control signals or configured to generate an address storage control signal based on the second and third operation control signals; and
a register configured to store an address relating to a storage location externally from the semiconductor device based on the address storage control signal.

16. A semiconductor system comprising:
a first semiconductor device configured to output first correction data obtained by correcting an error of first read data inputted through a transmission data signal as a correction data signal, configured to generate a write control signal according to the number of errors of the first read data, configured to output the first correction data included in the correction data signal through the transmission data signal based on the write control signal, and configured to output a command signal including a write command or a read command; and
a second semiconductor device configured to output the first read data through the transmission data signal outputted from a memory array or configured to store the first correction data into a memory cell of the memory array, based on the command signal.

17. The system of claim 16, wherein if the number of errors of the first read data is equal to or greater than a predetermined number, a verification operation starts and the first semiconductor device generates the write control signal.

18. The system of claim 17, wherein the first semiconductor device compares an error location of second read data inputted through the transmission data signal with an error location of the first read data to generate first to third operation control signals during the verification operation.

19. The system of claim 18,
wherein if the error location of the first read data is totally inconsistent with the error location of the second read data, the first operation control signal is enabled; and
wherein if the error location of the first read data is totally consistent with the error location of the second read data, the second operation control signal is enabled.

20. The system of claim 19, wherein if the second operation control signal is enabled, the second semiconductor device stores an address of the memory cell within the second semiconductor device.

21. A semiconductor device comprising:
an error correction circuit configured to output first correction data obtained by correcting an error of first read data inputted through a transmission data signal received, from a memory core circuit, as a correction data signal and configured to generate a write control signal according to the number of errors of the first read data; and
a verification operation control circuit configured to receive first correction data through the correction data signal to output the first correction data through an internal correction data signal and configured to generate an internal command signal for storing the first correction data into the memory core circuit, based on the write control signal.
